(19) United States
(12) Patent Application Publication
(10) Pub. No.: US 2025/0107112 A1
(43) Pub. Date: Mar. 27, 2025

(54) INDUCTORS FOR SEMICONDUCTOR PACKAGE SUBSTRATES

(71) Applicant: Intel Corporation, Santa Clara, CA (US)

(72) Inventors: Brandon C. MARIN, Gilbert, AZ (US); Srinivas PIETAMBARAM, Chandler, AZ (US); Mohammad Mamunur RAHMAN, Gilbert, AZ (US); Sashi Shekhar KANDANUR, Phoenix, AZ (US); Aleksandar ALEKSOV, Chandler, AZ (US); Tarek A. IBRAHIM, Mesa, AZ (US); Rahul N. MANEPALLI, Chandler, AZ (US)

(21) Appl. No.: 18/371,294

(22) Filed: Sep. 21, 2023

(51) Int. Cl. H01L 23/48; H01L 23/498

(52) U.S. Cl. CPC H10D 1/20; H01L 23/481; H01L 23/49822

(57) ABSTRACT

Coaxial magnetic inductor structures useful for semiconductor packaging applications are provided. The coaxial magnetic inductors can be located in semiconductor package cores and the semiconductor package cores can be, for example, comprised of an amorphous solid glass material. Methods of manufacturing a coaxial magnetic inductors in a package substrate core are also provided.

### FIELD

Descriptions are generally related to packaging for semiconductor chips, and more particular descriptions are related to inductors for semiconductor chip package substrates.

### BACKGROUND

The semiconductor chips that are central to intelligent devices and systems, such as personal computers, laptops, tablets, phones, servers, and other consumer and industrial products and systems, are packaged so that power can be delivered, data can be input and output, heat can be dissipated, and the chip can be protected from environmental challenges. Packaging of a semiconductor chip is extremely important to optimizing the performance longevity of the chip.

Packaging semiconductor devices presents a number of challenges and these challenges are amplified as devices become smaller and performance demands increase. Challenges include, for example, unwanted material interactions, precision and scaling requirements, heat management, power delivery requirements, limited failure tolerance, and material and manufacturing costs. Further, power delivery requirements for chips, such as, for example, those used in datacenters, are projected to increase two to three times over the next several years. Systems are needed that can support increased power delivery requirements.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention.

FIG. 1 provides an exemplary inductor structure in a section of a package substrate.

FIG. 2 shows a further exemplary inductor structure in a section of a package substrate.

FIG. 3 illustrates dimensions for exemplary inductor structures of FIGS. 1 and 2.

FIG. 4 illustrates a cross sectional view of the exemplary inductor structures of FIGS. 1 and 2.

FIGS. 5A and 5B describe an exemplary manufacturing process for an inductor structure.

FIG. 6 illustrates an additional exemplary manufacturing process for an inductor structure.

FIG. 7 provides a flow diagram of an example of a process for manufacturing a coaxial magnetic inductor.

FIG. 8 provides an example packaging assembly that includes coaxial magnetic inductors.

FIG. 9 provides an exemplary computing system in which coaxial magnetic inductors are employed.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrase “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine and/or physical operations. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions. The physical operations can be performed by, for example, semiconductor process equipment.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described, and includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, or semiconductor chip are used interchangeably and refer to a semiconductor device comprising integrated circuits.

The terms “package,” “packaging,” “IC package,” or “chip package,” “microelectronics package,” or “semiconductor chip package” are interchangeable and generally refer to an enclosed carrier of one or more dies, in which the dies are attached to a packaging substrate and encapsulated. The packaging substrate provides electrical interconnects between the die(s) and other dies and/or a motherboard or other printed circuit board for I/O (input/output) communication and power delivery. A package with multiple dies can be a system in a package for example.

A packaging substrate generally includes dielectric layers or structures having conductive structures on and/or embedded within the dielectric layers or structures. Other structures or devices are also possible within a packaging substrate. Semiconductor packaging substrates can have cores or be coreless.

A “core” or “package core” generally refers to a layer usually embedded within a packaging substrate. The core can provide structure or stiffness to a package substrate. A core is an optional feature of a packaging substrate. The core can be a dielectric organic or inorganic material and may have conductive vias extending through the layer. A package core can, for example, comprise glass (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy).

In further examples of a package substrate core, the substrate core is a glass core comprising an amorphous solid glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon (Si) and oxygen (O), as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight. Package substrate core compositions can vary depending on the product application.

Power delivery networks for semiconductor chips typically include voltage regulators (VRs) that are voltage regulating circuits. In one example, VRs are integrated into semiconductor chips and comprise part of the power delivery network. These integrated voltage regulators can be, for example, fully integrated voltage regulators (FIVR). Voltage regulation systems including integrated voltage regulators, such as, for example, FIVR, can be employed in chips that are used in data centers, among other places. Inductors located in semiconductor chip packages can be important parts of a power delivery network, such as, for example, a power delivery network comprising integrated voltage regulators.

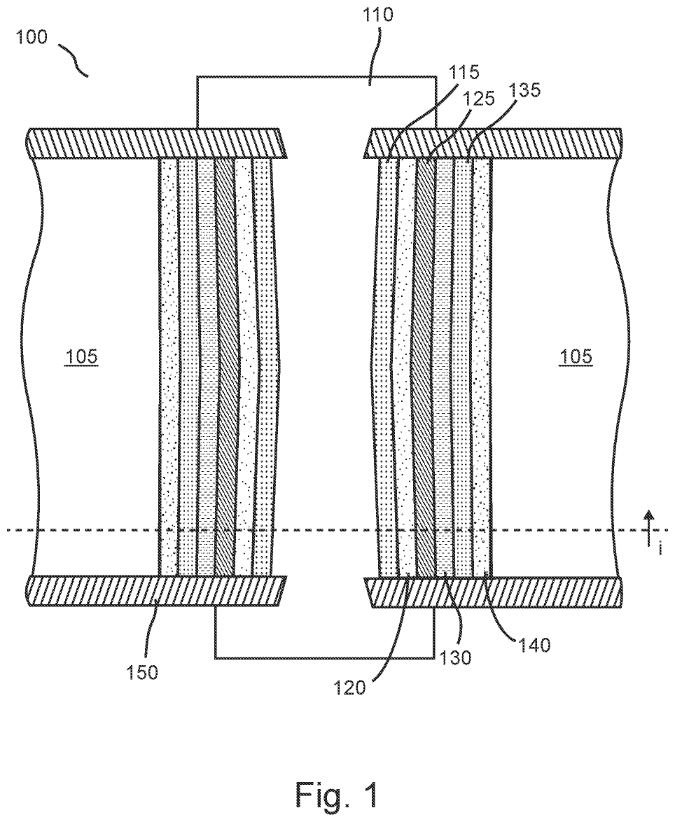

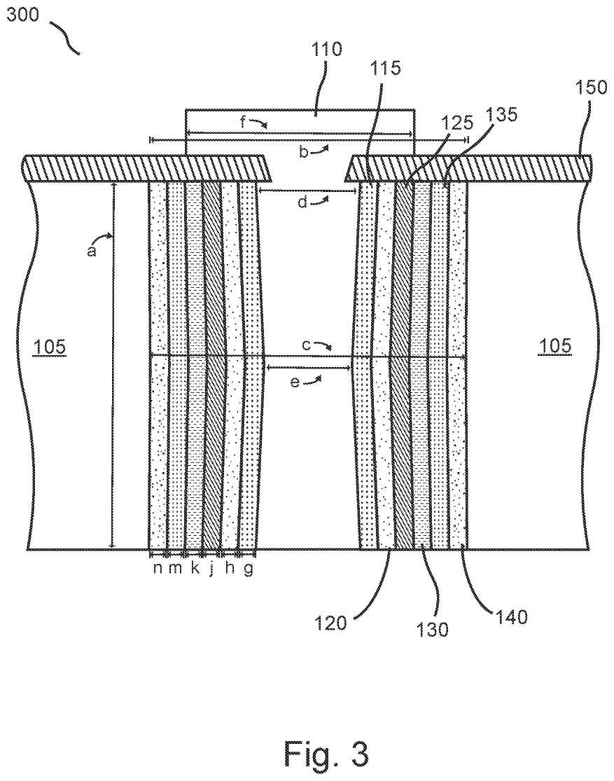

FIG. 1 illustrates an exemplary coaxial magnetic inductor structure. In FIG. 1, a section of a package substrate 100 is illustrated. The section of the package substrate 100 includes package substrate core 105 and includes an inductor structure that has a conducting through-core via 110, an optional conducting region seed layer 115, an adhesion layer 120, a polymeric layer 125, a magnetic layer 130, a magnetic region seed layer 135, and a package substrate core liner layer 140. In an exemplary package substrate, the package substrate core 105 is a glass core comprising an amorphous solid glass material as described herein. The package substrate core liner layer 140 can improve adhesion of subsequent layers to the package substrate core. Although the layers 115, 120, 125, 130, 135, and 140 are illustrated for simplicity as having approximately the same relative thicknesses, the thicknesses of the layers can instead be different relative thicknesses for some or all of the layers. FIG. 3 and the accompanying description provide some exemplary device dimensions for the coaxial magnetic inductor structure of FIG. 1.

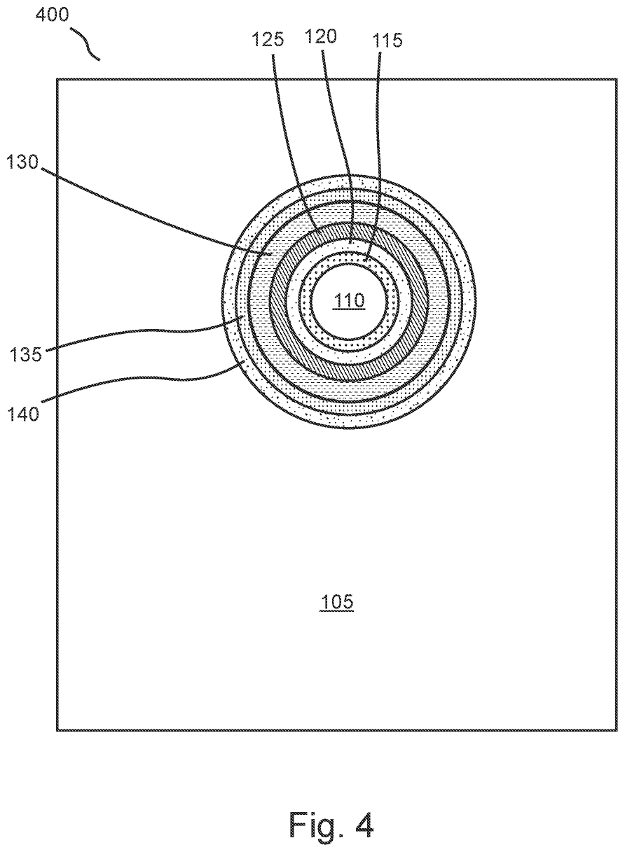

In FIG. 1, the conducting region 110 is comprised of, for example, a metal. The metal can be copper, silver, gold, or a combination thereof. Other metals or conducting materials are also possible for the conducting region 110. The optional conducting region seed layer 115 is, for example, comprised of copper, ruthenium (Ru), copper alloys, and/or oxides of Cu, Cu—Ti, Cu—Ta, and/or Cu—Ru (i.e., materials comprising Cu, Cu—Ti, Cu—Ta, and/or Cu—Ru and an amount of oxygen). Copper alloys can be, for example, alloys of copper and ruthenium, tantalum, and/or titanium. Other materials are possible for the optional conducting region seed layer 115. The adhesion layer 120 is comprised of, for example, Ti, or one of the materials described herein for the optional conducting region seed layer 115. In the case that the material is the same for the adhesion layer 120 and the conducting region seed layer 115, these layers are essentially the same and either one could be considered optional. For simplicity, the conducting region seed layer 115 has been described as optional herein even though either the adhesion layer 120 or the conducting region seed layer 115 could be considered optional depending on the choice of materials. The polymeric layer 125 is comprised of, for example, parylene, and/or an aliphatic or aromatic polymer. Useful aliphatic or aromatic polymers include polyvinyl and polypyrimidine. Other polymeric materials are possible, and one function that the polymeric layer can serve is to reduce mechanical stress in the multilayer coaxial magnetic inductor structure. A material that is compatible with the resulting coaxial magnetic inductor structure and manufacturing processes and that provides mechanical stress reduction is useful. In some examples, the polymeric layer 125 is optional, depending on the mechanical stress state of the semiconductor package assembly. The magnetic layer 130 is comprised of a magnetic material, such as, for example, a high permeability alloy. In examples of the invention, high permeability alloys have a magnetic permeability (u) of from 5 to 100. Useful magnetic materials include CoNiFeX, CoFe, CoFex, CoW, CoFeW, NiFe, and NiFeX where X is S, O, P, B, and/or V. The magnetic region seed layer 135 is comprised of, for example, Ru, Cu, or another atomic layer deposition-compatible material. Materials that are useful for the package substrate core liner layer 140 include, for example, Ti, Cr, TiCr, and TiN. Additional materials that are useful for the package substrate core liner 140 include, polymers, such as, for example, those described herein with respect to the polymeric layer 125. The section of the package substrate 100 additionally includes an organic layer 150, that is, for example, an organic buildup layer. The dashed line and arrow labeled “i” show the cross-sectional slice and direction of view for the device view shown in FIG. 4.

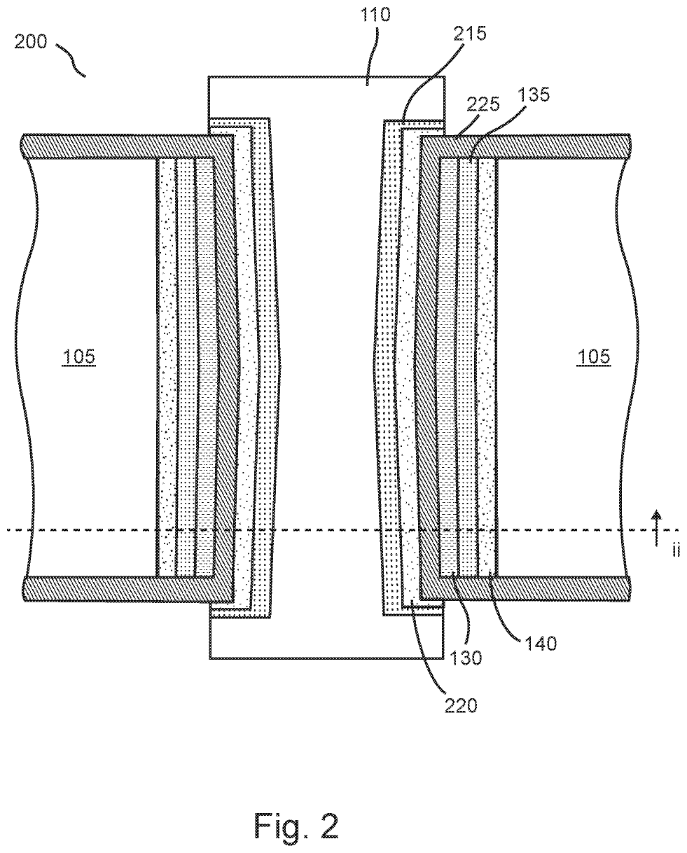

FIG. 2 shows an additional exemplary coaxial magnetic inductor device. In FIG. 2, the illustrated section of a package substrate 200, includes package substrate core 105 and includes an inductor structure that has a conducting through-core via 110, an optional conducting region seed layer 215, an adhesion layer 220, a polymeric layer 225, a magnetic layer 130, a magnetic region seed layer 135, and a package substrate core liner 140 layer. Descriptions and useful exemplary materials for parts of the illustrated section of a package substrate 200 that have the same numbers as parts described herein with respect to FIG. 1 are also applicable to FIG. 2. Additionally, the coaxial layers 215, 220, and 225, correspond to layers 115, 120, and 125, respectively, and the descriptions and exemplary materials for layers 115, 120, and 125, herein are applicable to layers 215, 220, and 225, respectively. For example, the package substrate core 105 can be a glass core comprising an amorphous solid glass material as described herein. Similar to FIG. 1, if the material is the same for the adhesion layer 220 and the conducting region seed layer 215, these layers are essentially the same and either one could be considered optional. The conducting region seed layer 215 has been described as optional herein even though either the adhesion layer 220 or the conducting region seed layer 215 could be considered optional depending on the choice of materials. In some examples according to FIG. 2 also, the polymeric layer 225 is optional, depending on the mechanical stress state of the semiconductor package assembly. Although the layers 215, 220, 225, 130, 135, and 140 are illustrated for simplicity as having approximately the same relative thicknesses, the thicknesses of the layers can instead be different relative thicknesses for some or all of the layers. FIG. 3 and the accompanying description provides some exemplary device dimensions for the coaxial magnetic inductor device of FIG. 2. The dashed line and arrow labeled “ii” show the cross-sectional slice and direction of view for the view shown in FIG. 4.

FIG. 3 provides an illustration of dimensions for parts of an exemplary coaxial magnetic inductor structure that is in a packaging substrate core. Although an exemplary device according to FIG. 1 has been used for the partial device illustration, the dimensions are useful also for examples according to FIG. 2. In FIG. 2, the coaxial layers 215, 220, and 225 are extended above the package substrate core 105, however, the dimensions illustrated for regions of corresponding coaxial layers 115, 120, and 125, respectively, are applicable to similarly-located regions of layers 215, 220, and 225. Although some exemplary dimensions are provided here, other dimensions are also possible. In FIG. 3, a section of a package substrate 300 is illustrated that includes a package substrate core 105 and also includes a partial inductor structure that has a conducting through-core via 110, an optional conducting region seed layer 115, an adhesion layer 120, a polymeric layer 125, a magnetic layer 130, a magnetic region seed layer 135, and a package substrate core liner layer 140. An exemplary thickness (double-ended arrow labeled “a” in FIG. 3) range for package substrate core 105 is between 50 and 2000 microns. An exemplary end diameter (double-ended arrow labeled “b” in FIG. 3) range for the through-core via is between 20 and 500 microns. An exemplary midsection diameter (double-ended arrow labeled “c” in FIG. 3) range for the through-core via is between 20 and 500 microns. An exemplary end section diameter range for the conducting region 110 (double-ended arrow labeled “d” in FIG. 3) is between 10 and 475 microns. An exemplary midsection diameter range for the conducting region 110 (double-ended arrow labeled “e” in FIG. 3) is 10 and 475 microns. An exemplary pad region diameter range for the conducting region 110 (double-ended arrow labeled “f” in FIG. 3) is between 20 and 500 microns. An exemplary end width range for a conducting region seed layer 115 region (double-ended arrow labeled “g” in FIG. 3) is 10 nm to 50 microns. An exemplary end width range for an adhesion layer 120 (double-ended arrow labeled “h” in FIG. 3) is 10 nm to 50 microns. An exemplary end width range for a polymeric layer 125 (double-ended arrow labeled “j” in FIG. 3) is 10 nm to 50 microns. An exemplary end width range for a magnetic layer 130 (double-ended arrow labeled “k” in FIG. 3) is 10 nm to 50 microns. An exemplary end width range for a magnetic region seed layer 135, (double-ended arrow labeled “m” in FIG. 3) is 10 nm to 50 microns. An exemplary end width range for a package substrate core adhesion layer 140 layer (double-ended arrow labeled “n” in FIG. 3) is 10 nm to 50 microns.

FIG. 4 provides a cut-through view of the exemplary coaxial magnetic inductor structures of FIGS. 1 and 2. Dashed lines “i” and “ii” and accompanying arrows show the plane and direction of the slice viewed in FIG. 4. The illustrated section of a package substrate 400, includes package substrate core 105 and includes an inductor structure that has a conducting through-core via 110, a conducting region seed layer 115 (layer 215 as shown in FIG. 2), an adhesion layer 120 (layer 220 as shown in FIG. 2), a polymeric layer 125 (layer 225 as shown in FIG. 2), a magnetic layer 130, a magnetic region seed layer 135, and a package substrate core liner 140.

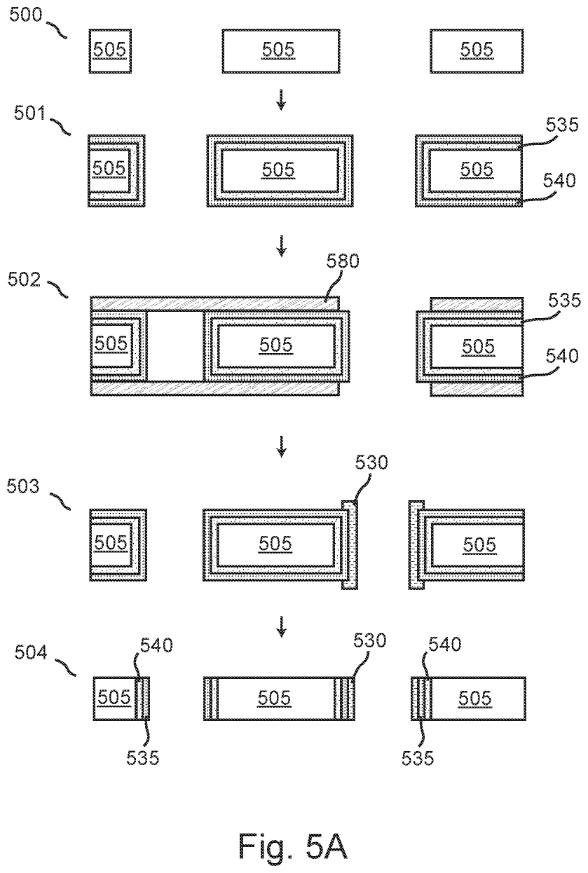

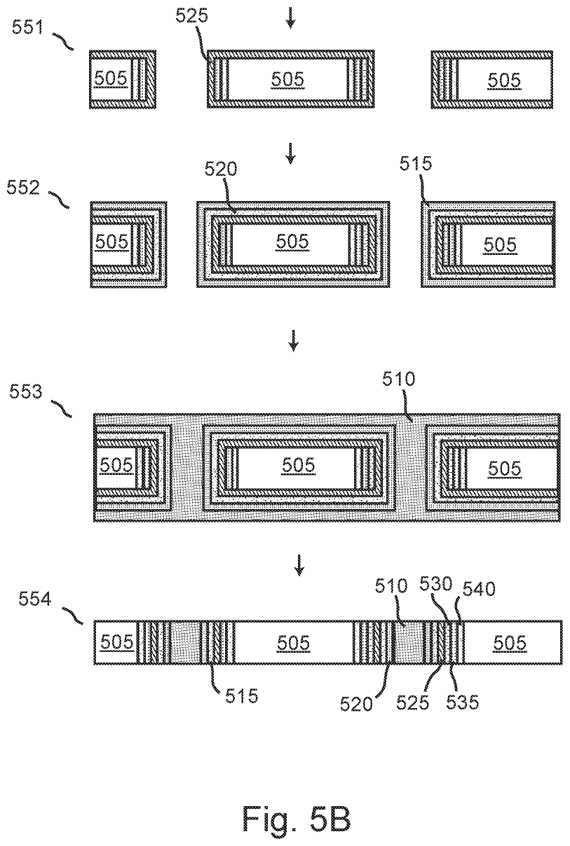

FIGS. 5A and 5B illustrate an exemplary manufacturing process useful for manufacturing a coaxial magnetic inductor structure such as that described by FIG. 1 herein. In FIG. 5A, a section 500 of a package substrate core 505 includes two through-holes. The package substrate core 505 can be a glass substrate comprising an amorphous solid glass material as described herein. A package substrate liner layer 540 comprising, for example, TiN, and a magnetic region seed layer 535 comprising, for example, Ru are then deposited by chemical vapor deposition (CVD) to create structure 501. In structure 502, a dry film resist (DFR) 580 has been laminated to two surfaces of the package substrate core 505. The DFR 580 is exposed and developed for through-hole plating of a magnetic material. In structure 503, a magnetic material layer 530 has been plated through a plated magnetic via (PMV) process using CVD or wet metallization and the DFR 580 has been stripped. In structure 504, layers 540 and 535 and magnetic material 530 have been removed from the package substrate core 505 surface through chemical mechanical polishing (CMP) and etching processes.

The manufacturing process of FIG. 5A is continued in FIG. 5B. In FIG. 5B, structure 551 shows that an optional polymeric layer 525 has been deposited. The polymeric layer 525 can be deposited using CVD. Structure 552 shows adhesion layer 520 and conducting region seed layer 515 have been deposited. Adhesion layer 520 and conducting region seed layer 515 can be deposited using CVD or wet metallization. Additionally, as described in examples herein, the adhesion layer 520 and the conducting region seed layer 515 and be the same material and layer. Structure 553 shows the creation of the conducting region 510 through, for example, a metal plating process. In structure 554, CMP and etching processes have been used to remove metal overburden and other materials from the package substrate core 505 surface. The resulting structure 554 has both a conducting non-magnetic through-core via and a magnetic (inductor) through-core via. Additional processing, such as lamination and via drill processes are used to create additional buildup layers (not shown).

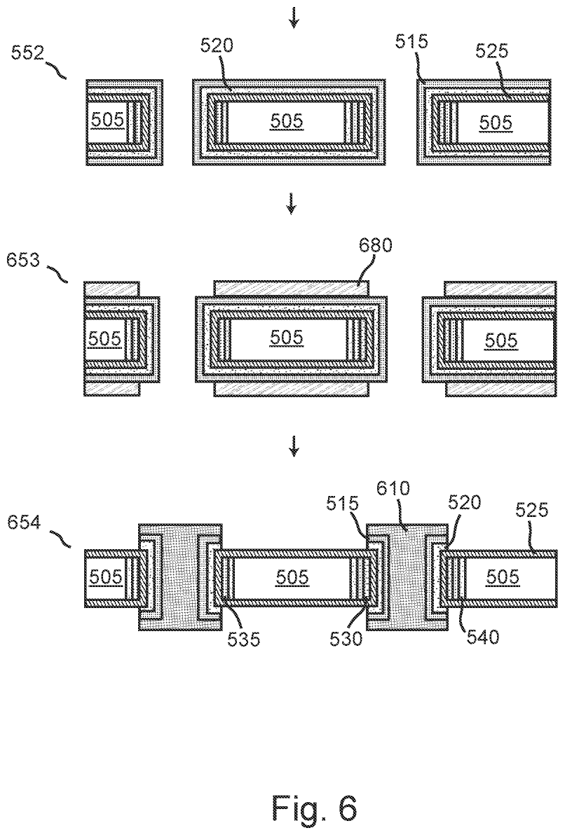

FIG. 6 provides a manufacturing process useful for creating coaxial magnetic inductors such as those described with respect to FIG. 2. Starting with structure 552 from FIG. 5B (which can be manufactured as described herein), DFR 680 is laminated to surfaces of the package substrate core 505, exposed and developed to create structure 653. Structure 654 shows the creation of the conducting region 610 through, for example, a metal plating process and DFR 680 removal through, for example, a wet stripping process. The resulting structure 654 has both a non-magnetic and a magnetic through-core vias.

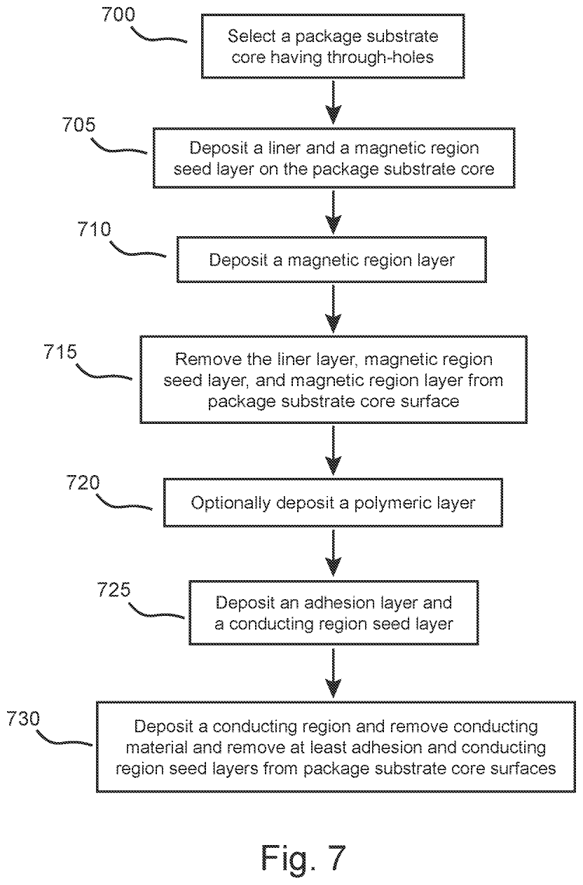

FIG. 7 diagrams a process for manufacturing a coaxial magnetic inductor in a package substrate core. A package substrate core is selected having through-holes 700. The package substrate core can be a glass core comprising an amorphous solid glass material as described herein. A package substrate core liner layer and a magnetic region seed layer are deposited on the package substrate core and into the through-holes 705. A magnetic region layer is deposited on the package substrate core and into the through-holes 710. One or more processes are performed (such as, for example, chemical mechanical polish and/or etch) to remove the package substrate core liner layer, the magnetic region seed layer, and the magnetic layer from opposing surfaces of the package substrate core 715. An optional polymeric layer is deposited 720. An adhesion and conducting region seed layer are deposited 725. In examples of coaxial inductors described herein, the adhesion layer and the conducting region seed layer are optionally the same material and layer. The conducting region material is deposited and the adhesion and conducting region seed layers are removed from package substrate core opposing surfaces 730. FIG. 7 provides an additional way of explaining the manufacturing processes of FIGS. 5A-5B and 6 and the details found herein with respect to these processes are applicable to FIG. 7. Additionally, the materials, structures, and explanations in FIGS. 1-3 and accompanying disclosure herein are also applicable to the process described for FIG. 7.

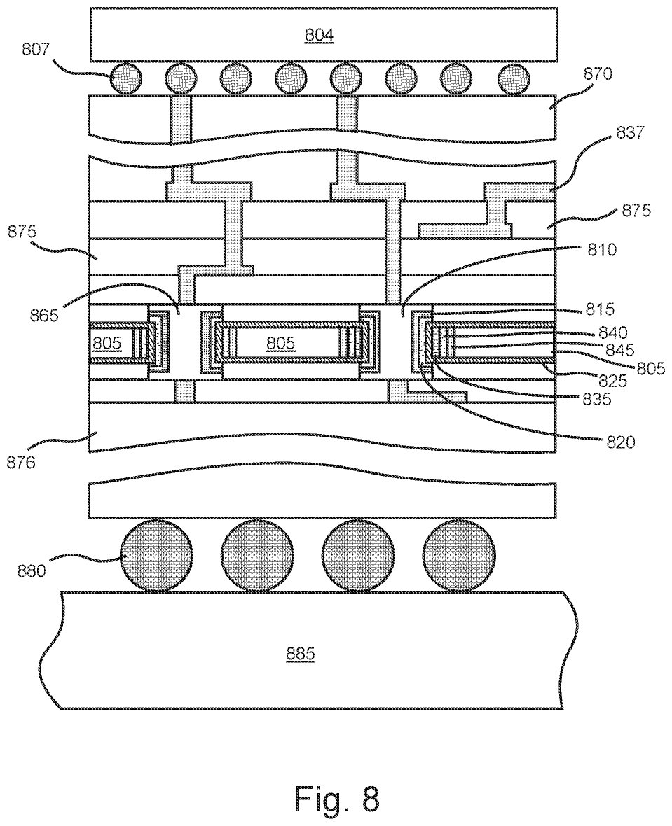

FIG. 8 shows an example section of a chip package assembly that includes a coaxial magnetic inductor in a chip package substrate. A chip package substrate can include a plurality of coaxial magnetic inductors (one illustrated). In FIG. 8, the parts and features are not necessarily illustrated relatively to scale. In FIG. 8, an example coaxial magnetic inductor according to FIGS. 2-4, 6, and 7 has been chosen, however any of the coaxial magnetic inductors described herein could be used in a similar manner (for example, the coaxial inductor of FIGS. 1, 3-4, 5A-5B, and 6 and accompanying description herein). The package structure of FIG. 8 includes a semiconductor chip 804, however, for ease of understanding, the structure shown does not include all the packaging layers and features that might be present in the semiconductor chip 804 package. For example, the end layer 870 shown in FIG. 8 would be unlikely to be the end surface of a packaged semiconductor chip in service as most packages, for example, further encapsulate a semiconductor chip 804. Further, a package structure could include additional semiconductor chips and chip interconnections (not shown). In the package structure shown in FIG. 8, the chip 804 is electrically coupled to the package through chip connectors 807. Chip connectors 807 could be pins, rods, bumps, or types of electrically conductive features used to join the chip 804 to a package substrate and provide power and communication. In examples of the invention, the chip 804 is one that includes integrated voltage regulators, such as, for example, FIVR. For clarity, only part of a complete chip package assembly is shown and layers, buildup layers, metal interconnects, devices, and features, for example, have been omitted.

In FIG. 8, package structure has board-side connectors 880 that are electrically and communicatively attached to contacts on a board 885 (which can be, for example, a motherboard, mainboard, main circuit board, printed circuit board, circuit board, system board, or logic board). The board-side connectors 880 can be solder balls, pins, pads, or other types of electrical contacts. The board-side connectors 880 can be a ball grid array (BGA), land grid array (LGA), or pin grid array (PGA) or for use with a LGA or PGA or for coupling to a socket feature of a motherboard. The package structure also contains other layers such as 875 and layers 876, that can be buildup layers, and metal interconnects 837. Additional metal interconnects, devices, and features (that are not shown), for example, can be present in layers 875 and 876 or in additional layers (not shown). The coaxial magnetic inductor can be part of a power delivery system for chip 804.

The package structure of FIG. 8 additionally illustrates a non-magnetic conducting through-core via 865 that can be created, for example, according to the processes described herein and by FIGS. 6 and 7 for creating a coaxial magnetic inductor in a package substrate core 805. A full package structure can include a plurality of conducting through-core vias 865. The coaxial magnetic inductor includes conducting through-core via 810, an optional conducting region seed layer 815, an adhesion layer 820, an optional polymeric layer 825, a magnetic layer 845, a magnetic region seed layer 835, and a package substrate core adhesion 840 layer. Descriptions for these layers and features are provided herein, for example, with respect to FIGS. 1-4. For example, the package substrate core 805 can be a glass core comprising an amorphous solid glass material as described herein.

Boards (or mainboard, main circuit board, printed circuit board, circuit board, system board, or logic board) such as those shown in FIG. 8 provide electrical contacts, i.e., power delivery and communication routes. Numerous electronic components can be housed on a motherboard, including processors (Central Processing Units (CPUs), graphics processing units (GPUs), digital signal processors (DSPs), coprocessors, network processors, etc.), accelerators, memory controllers, application-specific integrated circuits (ASICs), interface controllers, chipsets, systems in a chip, dual in-line memory modules (DIMMs) or RAM, non-volatile memory, power input and delivery connections, clock generators, BIOS (basic input/output system) chips, and interfaces and connectors peripherals and memory storage devices. The motherboard may contain slots or other types of connectors that accept DIMM or RAM cards, graphics cards or expansion cards. Additional connectors include, for example, Serial Advanced Technology Attachment (SATA) ports, and Peripheral Component Interconnect (PCI) and PCIe (PCI express) slots. Connectors for I/O devices such as peripherals can include, for example, high-definition multimedia interfaces (HDMI), Institute of Electrical and Electronics Engineers (IEEE) standard 1394 bus (Firewire) and universal serial bus (USB) connection receivers for mice, keyboards, storage devices, displays, and cameras, among other devices.

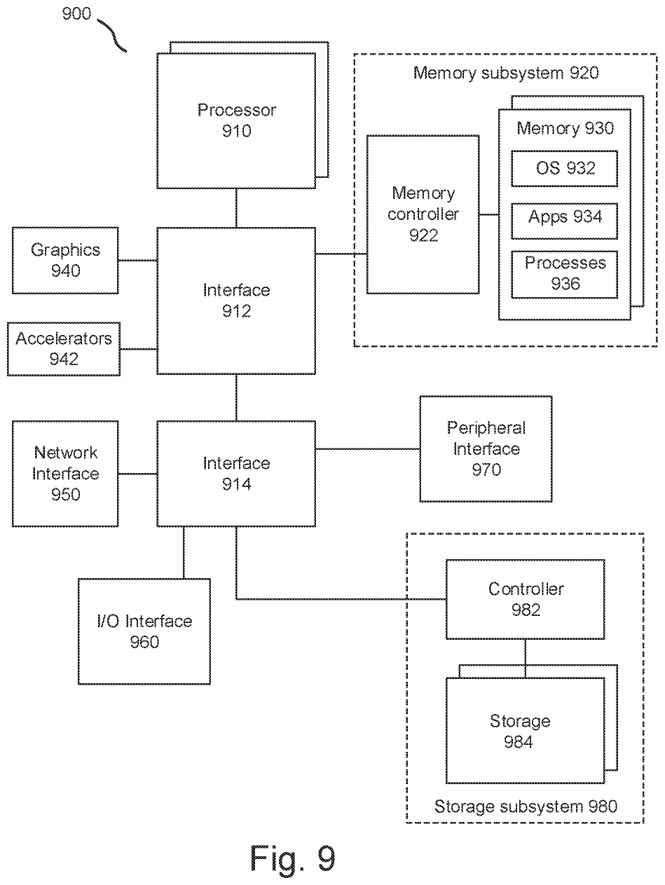

FIG. 9 depicts an example computing system which can be used in conjunction with devices that include coaxial magnetic inductors as described herein according to FIGS. 1-4, 5A-5B, and 6-8. As shown by FIG. 8 and the accompanying description, for example, one or more coaxial magnetic inductors can be included, for example, in the package used for a processor, microprocessors, accelerators, memory controllers and/or packages that include multiple chips and/or multiple types of chips. The packaged chips can be ones that include integrated voltage regulators. The computing system employed can include more, different, or fewer features than the one described with respect to FIG. 9.

Computing system 900 includes processor 910, which provides processing, operation management, and execution of instructions for system 900. Processor 910 can include any type of microprocessor, CPU (central processing unit), GPU (graphics processing unit), processing core, or other processing hardware to provide processing for system 900, or a combination of processors or processing cores. Processor 910 controls the overall operation of system 900, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 900 includes interface 912 coupled to processor 910, which can represent a higher speed interface or a high throughput interface for system components needing higher bandwidth connections, such as memory subsystem 920 or graphics interface components 940, and/or accelerators 942. Interface 912 represents an interface circuit, which can be a standalone component or integrated onto a processor die. Where present, graphics interface 940 interfaces to graphics components for providing a visual display to a user of system 900. In one example, the display can include a touchscreen display.

Accelerators 942 can be a fixed function or programmable offload engine that can be accessed or used by a processor 910. For example, an accelerator among accelerators 942 can provide data compression (DC) capability, cryptography services such as public key encryption (PKE), cipher, hash/authentication capabilities, decryption, or other capabilities or services. In some cases, accelerators 942 can be integrated into a CPU socket (e.g., a connector to a motherboard (or circuit board, printed circuit board, mainboard, system board, or logic board) that includes a CPU and provides an electrical interface with the CPU). For example, accelerators 942 can include a single or multi-core processor, graphics processing unit, logical execution unit single or multi-level cache, functional units usable to independently execute programs or threads, ASICs, neural network processors (NNPs), programmable control logic, and programmable processing elements such as field programmable gate arrays (FPGAs) or programmable logic devices (PLDs). Accelerators 942 can provide multiple neural networks, CPUs, processor cores, general purpose graphics processing units, or graphics processing units can be made available for use by artificial intelligence (AI) or machine learning (ML) models.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 930 stores and hosts, among other things, operating system (OS) 932 that provides a software platform for execution of instructions in system 900, and stores and hosts applications 934 and processes 936. In one example, memory subsystem 920 includes memory controller 922, which is a memory controller to generate and issue commands to memory 930. The memory controller 922 could be a physical part of processor 910 or a physical part of interface 912. For example, memory controller 922 can be an integrated memory controller, integrated onto a circuit within processor 910.

System 900 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe), a Hyper Transport or industry standard architecture (ISA) bus, a small computer system interface (SCSI) bus, a universal serial bus (USB), or a Firewire bus.

In one example, system 900 includes interface 914, which can be coupled to interface 912. In one example, interface 914 represents an interface circuit, which can include standalone components and integrated circuitry. In one example, user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB, or other wired or wireless standards-based or proprietary interfaces. Network interface 950 can transmit data to a device that is in the same data center or rack or a remote device, which can include sending data stored in memory.

Some examples of network interface 950 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include additional types of hardware interfaces, such as, for example, interfaces to semiconductor fabrication equipment and/or electrostatic charge management devices.

In one example, system 900 includes storage subsystem 980. Storage subsystem 980 includes storage device(s) 984, which can be or include any conventional medium for storing data in a nonvolatile manner, such as one or more magnetic, solid state, and/or optical based disks. Storage 984 can be generically considered to be a “memory,” although memory 930 is typically the executing or operating memory to provide instructions to processor 910. Whereas storage 984 is nonvolatile, memory 930 can include volatile memory (e.g., the value or state of the data is indeterminate if power is interrupted to system 900). In one example, storage subsystem 980 includes controller 982 to interface with storage 984. In one example controller 982 is a physical part of interface 912 or processor 910 or can include circuits or logic in both processor 910 and interface 914.

A power source (not depicted) provides power to the components of system 900. More specifically, power source typically interfaces to one or multiple power supplies in system 900 to provide power to the components of system 900.

Exemplary systems may be implemented in various types of computing, smart phones, tablets, personal computers, and networking equipment, such as switches, routers, racks, and blade servers such as those employed in a data center and/or server farm environment.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A microelectronics device comprising:
a package substrate core wherein the package substrate core comprises an amorphous solid glass material and wherein the package substrate core has a through-core via;
a conducting region in the through-core via; and
a plurality of layers between the conducting region and the package substrate core wherein the plurality of layers includes an adhesion layer, a magnetic layer, and a package substrate core liner layer.

2. The microelectronics device of claim 1 additionally including a polymeric layer that is between the conducting region and the package substrate core.

3. The microelectronics device of claim 1 wherein the plurality of layers additionally includes a conducting region seed layer that is between the conducting region and the package substrate core.

4. The microelectronics device of claim 1 wherein the plurality of layers additionally includes a magnetic region seed layer.

5. The microelectronics device of claim 1, wherein the magnetic layer comprises CoNiFeX, CoFe, CoFeX, CoW, CoFeW, NiFe, or NiFeX.

6. The microelectronics device of claim 2 wherein the polymeric layer comprises an aliphatic or aromatic polymer.

7. The microelectronics device of device of claim 2 wherein the polymeric layer comprises parylene, a polypyrimidine polymer, or a polyvinyl polymer.

8. The microelectronics device of claim 1 wherein the magnetic layer has a thickness that is between 10 nm and 5 microns.

9. The microelectronics device of claim 1 wherein the package substrate core comprises aluminosilicate, borosilicate, alumino-borosilicate, silica, or fused silica.

10. The microelectronics device of claim 1 wherein the package substrate core comprises aluminosilicate, borosilicate, alumino-borosilicate, silica, or fused silica, and wherein the package substrate core additionally comprises Al₂O₃, B₂O₃, MgO, CaO, SrO, BaO, SnO₂, Na₂O, K₂O, SrO, P₂O₃, ZrO₂, Li₂O, Ti, Zn, or a combination thereof.

11. A microelectronics assembly comprising:
a semiconductor chip;
a semiconductor package substrate wherein the semiconductor chip is electrically coupled to the semiconductor package substrate and wherein the semiconductor package substrate includes a plurality of layers comprising metal interconnects; and
a semiconductor package substrate core wherein the semiconductor package substrate core is in the semiconductor package substrate, wherein layers of the plurality of layers comprising metal interconnects are located on at least one side of the semiconductor package substrate core; wherein the semiconductor package substrate core comprises an amorphous solid glass material, wherein the semiconductor package substrate core has a through-core via, wherein the through-core via comprises a conducting region and a plurality of layers between the conducting region and the package substrate core, and wherein the plurality of layers includes an adhesion layer, a polymeric layer, a magnetic layer, and a package substrate core liner layer.

12. The microelectronics assembly of claim 11 wherein the semiconductor chip comprises an integrated voltage regulator.

13. The microelectronics assembly of claim 11 additionally comprising a circuit board wherein the semiconductor package substrate is electrically coupled to the circuit board.

14. The microelectronics assembly of claim 11 wherein the magnetic layer comprises CoNiFeX, CoFe, CoFeX, CoW, CoFeW, NiFe, or NiFeX.

15. The microelectronics assembly of claim 11 wherein the polymeric layer comprises aliphatic or aromatic polymer.

16. The microelectronics assembly of claim 11 wherein the magnetic layer has a thickness that is between 10 nm and 5 microns.

17. The microelectronics assembly of claim 11 wherein the package substrate core comprises aluminosilicate, borosilicate, alumino-borosilicate, silica, or fused silica.

18. A method for manufacturing a magnetic inductor structure comprising:
depositing a package substrate core liner layer into a through-hole in a package substrate core wherein the package substrate core is comprised of a solid amorphous glass material;
depositing a seed layer for a magnetic material into the through-hole in the package substrate core;
depositing a magnetic material layer into the through-hole in the package substrate core;
depositing a polymeric layer into the through-hole in the package substrate core;
depositing an adhesion into the through-hole in the package substrate core;
depositing a conducting region seed layer into the through-hole in the package substrate core; and
depositing a conducting material into the through-hole in the package substrate core.

19. The method of claim 18 also including removing the package substrate core liner layer from a surface of the package substrate core.

20. The method of claim 18 wherein the package substrate core comprises aluminosilicate, borosilicate, alumino-borosilicate, silica, or fused silica.
